(19) United States
(12) Patent Application Publication
(10) Pub. No.: US 2025/0380463 A1
(43) Pub. Date: Dec. 11, 2025

(54) DOG BONE CHANNEL FET WITH NO INNER SPACER

(71) Applicant: INTERNATIONAL BUSINESS MACHINES CORPORATION, Armonk, NY (US)

(72) Inventors: Ruilong Xie, Niskayuna, NY (US); Debarghya Sarkar, Latham, NY (US); Chen Zhang, Santa Clara, CA (US); Julien Frougier, Albany, NY (US)

(21) Appl. No.: 18/738,635

(22) Filed: Jun. 10, 2024

(51) Int. Cl. H01L 29/786; H01L 29/06; H01L 29/08; H01L 29/423; H01L 29/66; H01L 29/775

(52) U.S. Cl. CPC H10D 30/6757; H10D 30/014; H10D 30/031; H10D 30/43; H10D 30/6735; H10D 62/121; H10D 62/151; H10D 64/017; H10D 64/018

(57) ABSTRACT

A semiconductor device includes source/drain regions having a main portion and a buffer layer partially encapsulating the main portion. Dog bone channels extend across a gate conductor and connect between the buffer layer at end portions of the dog bone channels. The end portions are thicker than a central portion of the dog bone channels.

### BACKGROUND

The present invention generally relates to semiconductor devices and processing methods, and more particularly to nanosheet field effect transistor (FET) channels.

Various techniques have been employed to attempt to introduce strain in channel material. For example, tensile strain can be introduced for higher electron mobility, and compressive strain for higher hole mobility. However, a disparity exists between the electron and hole mobility, especially in silicon. Device function is improved when the hole mobility approaches the electron mobility. This once required large size differences between P-type metal oxide semiconductor (PMOS) devices and N-type metal oxide semiconductor (NMOS) devices. The transition to a nanosheet channel of very small thickness exacerbates the difficulty in providing improved P-type field effect transistor (PFET) device characteristics.

### SUMMARY

In accordance with an embodiment of the present invention, a semiconductor device includes source/drain regions having a main portion and a buffer layer partially encapsulating the main portion. Dog bone channels extend across a gate conductor and connect between the buffer layer at end portions of the dog bone channels. The end portions are thicker than a central portion of the dog bone channels.

In accordance with another embodiment of the present invention, a semiconductor device includes a gate structure having a gate conductor having a lower portion disposed between source/drain regions and an upper portion. Dog bone channels extend through the gate conductor and connect between the source/drain regions. Spacers are disposed on sidewalls of the upper portion. The source/drain regions include a main portion and a buffer layer encapsulating the main portion. The buffer layer contacts end portions of the dog bone channels. The end portions are thicker than a central portion of the dog bone channels.

In accordance with another embodiment of the present invention, a semiconductor device includes a gate structure having a gate conductor having a lower portion disposed between source/drain regions and an upper portion. Dog bone channels extend through the gate conductor and connect between the source/drain regions. Spacers are disposed on sidewalls of the upper portion, and a gate dielectric is disposed over the dog bone channels and a surface of the spacers. The source/drain regions include a main portion and a buffer layer encapsulating the main portion. The buffer layer has a uniform thickness that encapsulates lateral sides of the main portion. The buffer layer contacts end portions of the dog bone channels. The end portions are thicker than a central portion of the dog bone channels.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view, taken at section line X, and a layout view showing section lines X and Y of a semiconductor substrate and a nanosheet applied thereto, in accordance with an embodiment of the present invention;

FIG. 2 shows cross-sectional views, taken at section lines X and Y, of the patterned nanosheet and a shallow trench isolation region formed, in accordance with an embodiment of the present invention;

FIG. 3 shows cross-sectional views, taken at section lines X and Y, after forming dummy gate structures and gate spacers, in accordance with an embodiment of the present invention;

FIG. 4 shows cross-sectional views, taken at section lines X and Y, after recessing semiconductor layers in a gate area, in accordance with an embodiment of the present invention;

FIG. 5 shows cross-sectional views, taken at section lines X and Y, after forming fillers in recesses between semiconductor layers in the gate area, in accordance with an embodiment of the present invention;

FIG. 6 shows cross-sectional views, taken at section lines X and Y, after ball etching the fillers, the semiconductor layers and the substrate to provide a recess, in accordance with an embodiment of the present invention;

FIG. 7 shows cross-sectional views, taken at section lines X and Y, after growing a buffer layer in the recess and growing a main portion on the buffer layer for source/drain regions, in accordance with an embodiment of the present invention;

FIG. 8 shows cross-sectional views, taken at section lines X and Y, after depositing and planarizing a dielectric layer for an interlayer dielectric, in accordance with an embodiment of the present invention;

FIG. 9 shows cross-sectional views, taken at section lines X and Y, after removing dummy gates, in accordance with an embodiment of the present invention;

FIG. 10 shows cross-sectional views, taken at section lines X and Y, after removing the semiconductor layers where the fillers are located, in accordance with an embodiment of the present invention;

FIG. 11 shows cross-sectional views, taken at section lines X and Y, after etching the semiconductor layers to form dog bone channels, in accordance with an embodiment of the present invention; and

FIG. 12 shows cross-sectional views, taken at section lines X and Y, after forming a gate dielectric and gate conductor over the dog bone channels, in accordance with an embodiment of the present invention.

### DETAILED DESCRIPTION

In accordance with embodiments of the present invention, devices and methods are described which include dog bone shaped channels or dog bone channels in a nanosheet structure. The dog bone channels are formed without employing inner spaces within the structures. By eliminating the inner spacers, compressive strain is easier to maintain within the structure. With increased or higher compressive strain, P-type field effect transistor (PFET) devices can include a higher hole mobility that is more on par with N-type field effect transistor (NFET) devices and electron mobility. In addition, greater short channel effect (SCE) control can be achieved.

In an embodiment, a semiconductor device includes a nanosheet device with a dog bone channel. A high-K dielectric surrounds the dog bone channel and includes a gate dielectric layer. The high-K dielectric directly contacts a source/drain buffer layer for a source/drain region to which the dog bone channel connects. The dog bone channel includes a necked down center portion where a thickness is narrower and further includes a thicker portion towards connection regions of source/drain regions at opposing ends of the dog bone channel. A width of dog bone channel sheet is less than an original width of an active region as the width of a layout area of the dog bone channel is also reduced (e.g., Wsheet<W of active region island). The end portions of the dog bone channel also extend a distance that can overlap with a gate spacer, making the dog bone channel longer and thicker to improve short channel effects. The high-k gate dielectric layer can also extend to overlap with the gate spacer.

In an embodiment, a semiconductor device includes source/drain regions having a main portion and a buffer layer partially encapsulating the main portion. Dog bone channels extend across a gate conductor and connect between the buffer layer at end portions of the dog bone channels. The end portions are thicker than a central portion of the dog bone channels. The gate conductor can include a portion in contact with the buffer layer which overlaps with a width of gate spacers on an upper portion of a gate structure. The gate conductor includes a gate dielectric that can have a portion in contact with the buffer layer which overlaps with the width of the spacers.

In another embodiment, a method for forming semiconductor device includes providing nanosheets having high SiGe content sacrificial layers, which alternate with Si layers in the nanosheet structure, on a substrate. A dummy gate is formed followed by gate spacers. The nanosheet is recessed to pattern channel structures. The high SiGe content sacrificial layers are laterally recessed (indented), and a low SiGe content sacrificial layer is formed in indented cavities of the laterally recessed high SiGe content sacrificial layers. A monocrystalline buffer layer is formed followed by epitaxial growth of source/drain regions. A poly-open chemical mechanical polish liner (POC liner) can be formed over the source/drain regions. The dummy gate is removed followed by the removal of the high SiGe content sacrificial layer. Next, the low SiGe content layer is removed with sheet trimming of the Si layers. Replacement high-dielectric constant metal gates HKMG are formed in locations where the dummy gates were removed.

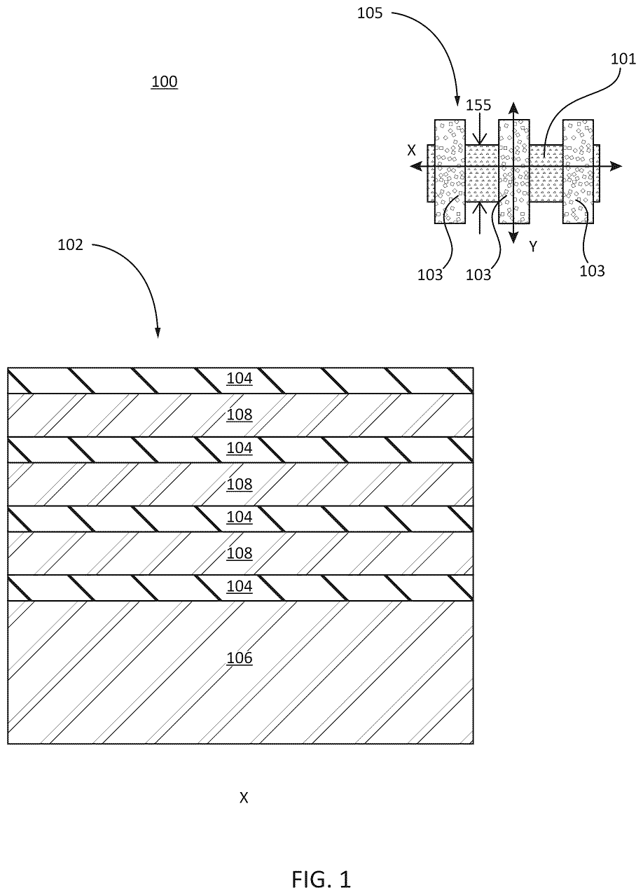

Referring now to the drawings in which like numerals represent the same or similar elements and initially to FIG. 1, devices and methods for manufacturing a nanosheet field effect transistor (FET) device are shown in accordance with embodiments of the present invention. A wafer 100 includes a substrate 106. The substrate 106 can include a single layer or multiple layers on which nanosheet FET device will be fabricated. FIG. 1 depicts a cross-sectional view indicated by X taken at section line X in a layout view in inset 105. Cross-sectional views X and Y are taken at corresponding sections X and Y in the inset 105. The inset 105 shows gate lines 103 and an active region line 101 or active region island for reference. Corresponding X and Y views are depicted throughout FIGS. 1-12. Active region line 101 represents source/drain (S/D) regions for transistor devices to be formed. Gate lines 103 are also represented for such transistor devices. Transistor channels are formed on the active region line 101 below the gate lines 103.

The substrate 106 can include any suitable substrate structure, e.g., a bulk semiconductor, a semiconductor-on-insulator (SOI) substrate, etc., and preferably includes a monocrystalline semiconductor. In an example, the substrate 106 can include a silicon-containing material.

Illustrative examples of silicon-containing materials suitable for the substrate 106 can include, but are not limited to, Si, SiGe, SiGeC, SiC and multi-layers thereof. Although Si is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A layer stack or stacks are applied to or formed on the substrate 106. In an embodiment, nanosheet (NS) 102 is applied or bonded to the substrate 106. In another embodiment, the layer stack can be epitaxially grown using different chemistries to form layers having different properties. The nanosheet 102 includes alternating layers of semiconductor material having distinct properties to permit the formation of semiconductor channels in accordance with embodiments of the present invention. For example, semiconductor layers 104 have semiconductor layers 108 interposed therebetween. In an embodiment, semiconductor layers 104 are selectively removeable relative to the semiconductor layers 108 and vice versa, e.g., by selective etching. In an embodiment, the semiconductor layers 104 include SiGe, and in particular, high content SiGe where Ge is from about 30 atomic % of the compound to about 45 atomic % of the compound, and more specifically, where Ge is from about 35 atomic % of the compound to about 40 atomic % of the compound. In this embodiment, the semiconductor layers 108 include Si. The semiconductor layers 104 and the semiconductor layers 108 are monocrystalline or predominantly monocrystalline. It should be understood that other materials or atomic percentages can be employed for semiconductor layers 104 and 108. In other embodiments, different stack orders and numbers may be employed for semiconductor layers 104 and 108.

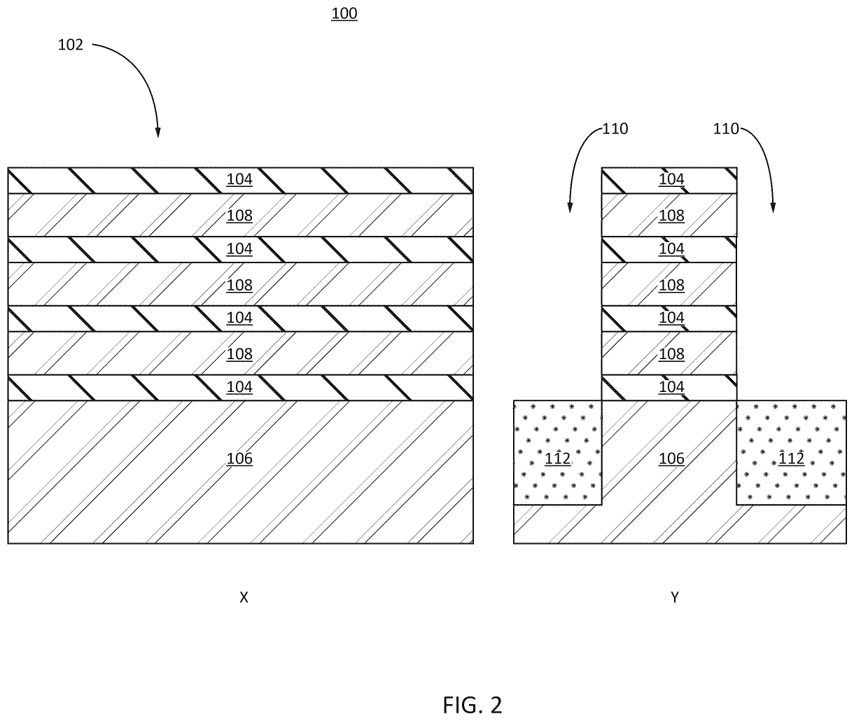

Referring to FIG. 2, the nanosheet 102 can be patterned. In an embodiment, a hard mask (not shown) may be formed by blanket depositing a layer of hard mask material, providing a patterned photoresist on top of the layer of hard mask material, and then etching the layer of hard mask material to provide a hard mask pattern for etching the nanosheet 102. The hard mask material can include a photoresist or be patterned by a photoresist, which can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Openings 110 can be formed through nanosheet 102 down to the substrate 106. Openings 110 can be formed using an anisotropic etch process, such as a reactive ion etch (RIE) or an ion beam etch (IBE). The substrate 106 is further etched to form shallow trenches therein in accordance with openings 110. Shallow trench isolation (STI) or STI regions 112 are formed in the etched trenches. STI regions 112 can be formed by depositing dielectric material, such as, e.g., SiO₂, SiOₓN_{y}, SiCO or other suitable compounds. STI regions 112 can be deposited using chemical vapor deposition (CVD), although other deposition methods can be employed. The STI regions 112 can then be etched, e.g., by RIE, to a level of the substrate 106.

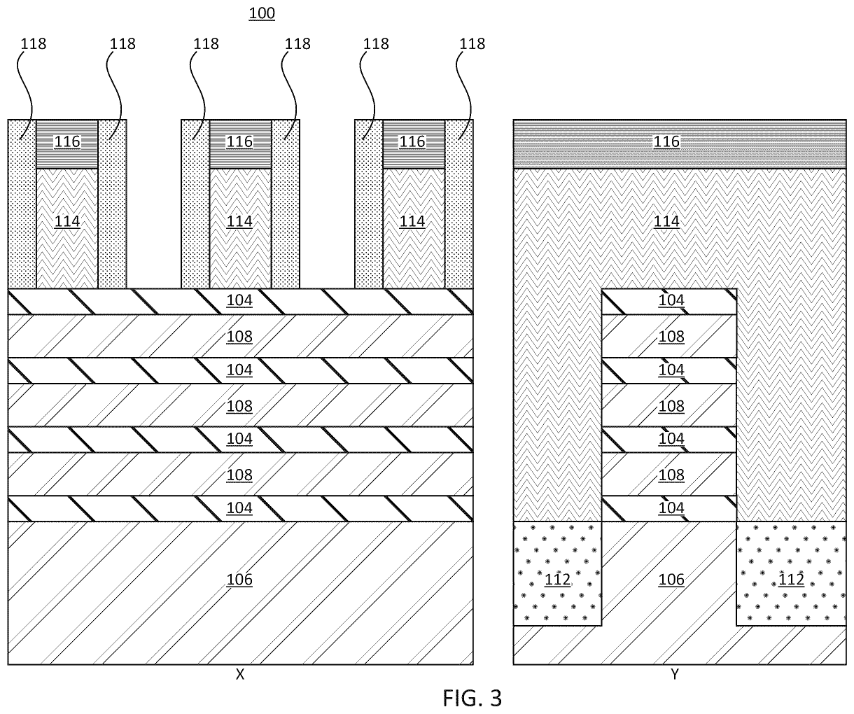

Referring to FIG. 3, a dummy gate material for dummy gates 114 is blanketed over the wafer 100 followed by a blanket deposition of a hard mask material to later form patterned hard mask 116, e.g., by using photolithographic patterning. The dummy gate material can include a polysilicon, amorphous Si or other selectively removeable material. The hard mask 116 is employed to etch the dummy gates 114. Then, a deposition process is employed followed by an etch process to form spacers 118 in upper portions of gate structures. Spacers 118 can include an oxide, such as silicon dioxide, a nitride, such as silicon nitride, although other dielectric materials can be employed.

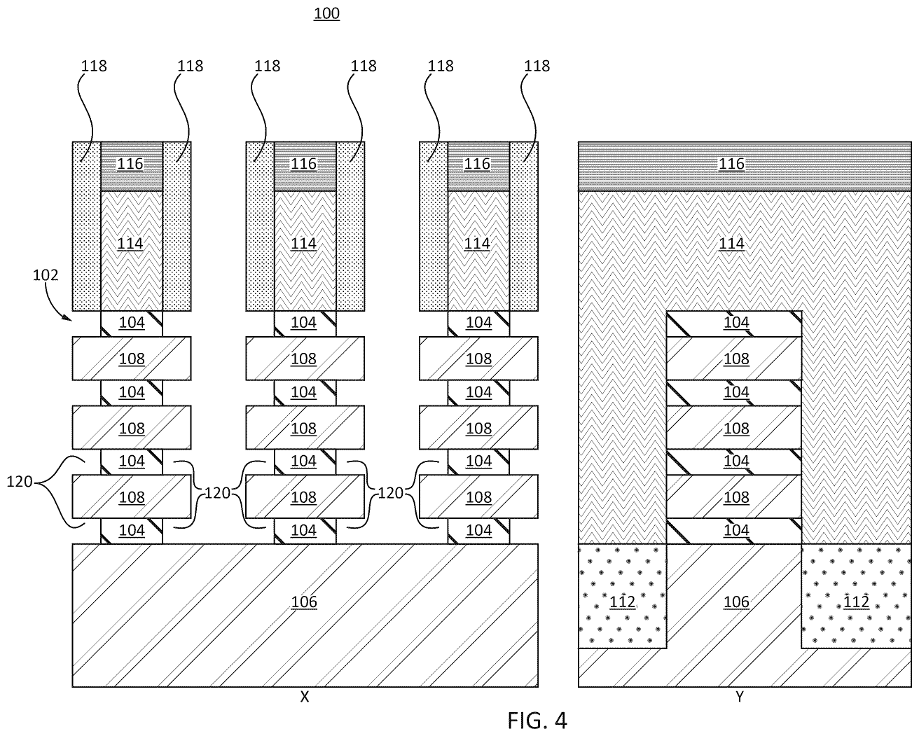

Referring to FIG. 4, the hard mask 116 and spacers 118 can be employed as an etch mask to recess the nanosheet 102 to expose the substrate 106. Regions of the nanosheet 102 below the hard mask 116 and spacers 118 are patterned for further processing.

An indentation etch process is performed to create indentations or recesses 120 in the semiconductor layers 104 in a lower portion of the gate structures. The indentation etch process can include a wet or dry etch that selectively removes the material of the semiconductor layers 104 relative to the semiconductor layers 108, the hard mask 116, the spacers 118 and the substrate 106. The recesses 120 can include a recess depth that can extend up to or beyond a width of the dummy gate 114, although the recess depth can include other dimensions.

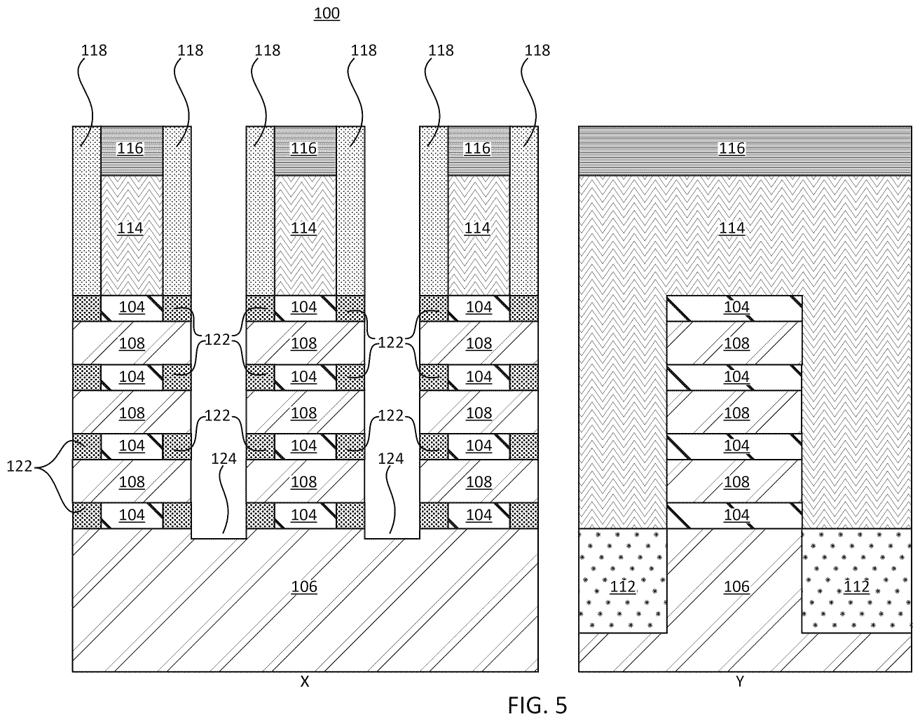

Referring to FIG. 5, a selective deposition process is performed to epitaxially grow fillers 122 within the recesses 120 (FIG. 4) in contact with the semiconductor layers 104. For selective deposition, the fillers 122 need to include a composition that is similar to semiconductor layers 104. However, the fillers 122 need to provide a different etch selectivity than the semiconductor layers 104. This different etch selectivity between fillers 122 and the semiconductor layer 104 provides for a reduced removal rate of the semiconductor layer 108 when forming dog bone channels in later steps. In an embodiment, the semiconductor layers 104 can include SiGe at a higher concentration (to provide a high SiGe content sacrificial layer) than a SiGe concentration of the filler 122 (to provide a low SiGe content sacrificial layer). In one example, if the SiGe concentration of the semiconductor layers 104 includes SiGe from between about 35-40 atomic % than the fillers 122 can include a SiGe concentration of between about 15 to about 20 atomic %. After the fillers 122 have been formed, an etch process is performed to remove excess material of the fillers 122. The etch process can remove a small portion 124 of the substrate 106.

Note that the fillers 122 are not inner spacers. The fillers 122 include a semiconductor material and will be consumed in later steps.

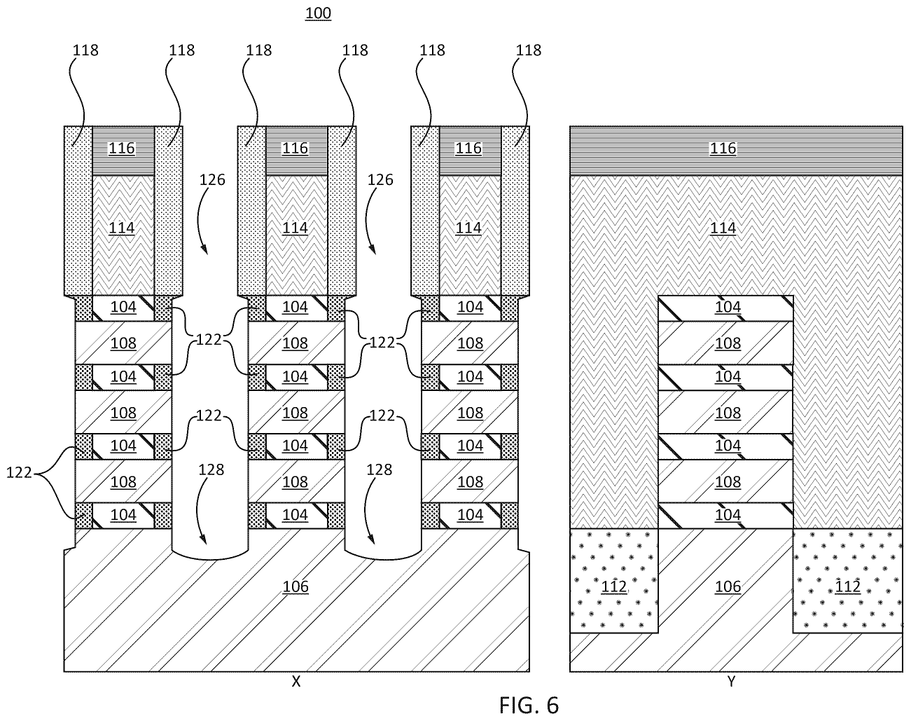

Referring to FIG. 6, an anisotropic etch process, such as a ball etch, is performed to recess the semiconductor layers 108, fillers 122 and extend and round out a bottom portion 128 in the substrate 106. The anisotropic etch process cleans and smooths surfaces within spacings 126 and creates space for a buffer layer to be formed in later steps.

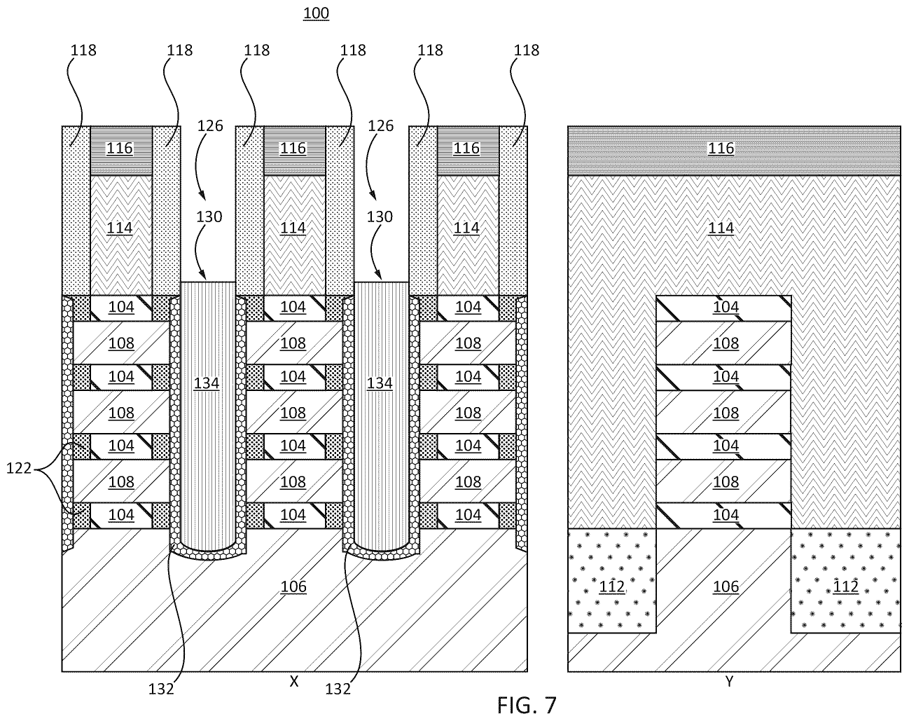

Referring to FIG. 7, source/drain regions 130 are formed within the spacings 126. An epitaxial growth process is performed to form a buffer layer 132 in the recess formed in FIG. 6. The epitaxial growth process is initiated on the substrate 106 and the semiconductor layers 104 and 108. The buffer layer 132 includes a monocrystalline or predominantly monocrystalline structure and can include a uniform thickness. In an embodiment, atomic layer deposition (ALD) can be employed to deposit the buffer layer 132. The buffer layer 132 can include Si, and, in particular a lightly doped Si, with dopants in accordance with N-type or P-type devices.

The buffer layer 132 is employed to initiate epitaxial growth of main portions 134 of the source/drain regions 130. The main portions 134 are employed along with the buffer layer 132 to form the source/drain regions 130 for transistors of the nanosheet FET device under construction on the wafer 100. The main portions 134 can include Si or SiGe. In an embodiment, the main portions 134 can be designated as P-type or N-type devices. In an example, if the main portions 134 include N-type devices then the main portions 134 can include Si. In another example, if the main portions 134 include P-type devices then the main portions 134 can include SiGe.

The main portions 134 can be appropriately doped during their formation by epitaxial growth. For example, the main portions 134 can be doped by introducing p dopants (e.g., B, Ga, etc.) during epitaxial formation. Similarly, the main portions 134 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

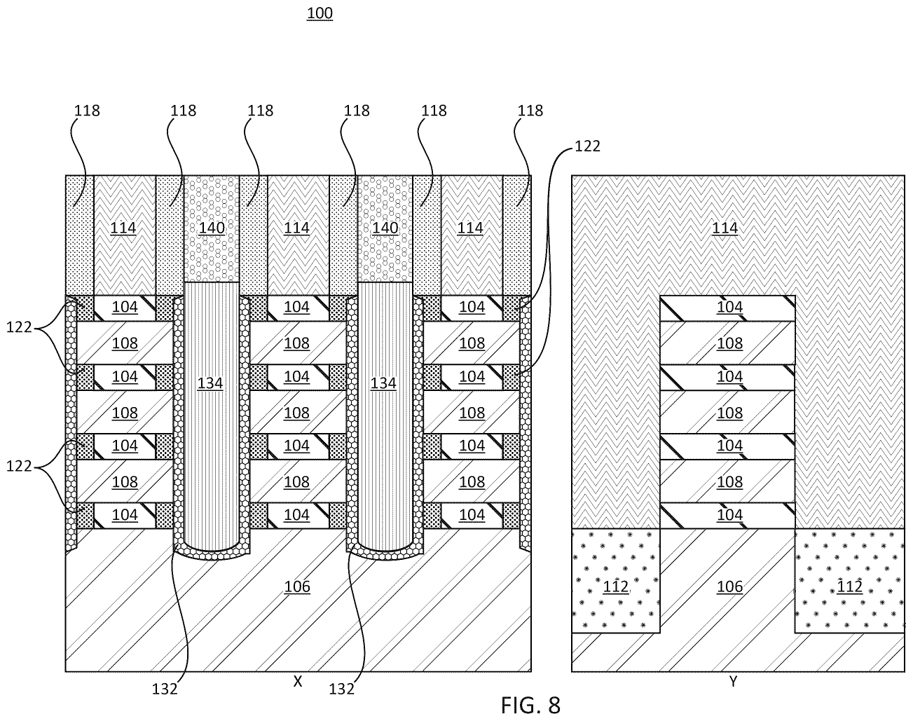

Referring to FIG. 8, a dielectric layer 140, such as, e.g., an interlayer dielectric (ILD) is formed on the wafer 100. The dielectric layer 140 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C: H). The dielectric layer 140 can be deposited using chemical vapor deposition (CVD), although other deposition methods can be employed.

A planarization process can be performed to planarize a top surface of the wafer 100. In an embodiment, the planarization process can include a chemical mechanical polish (CMP). The planarization process removes excess material of the dielectric layer 140, removes the hard mask 116 and exposes the dummy gate 114.

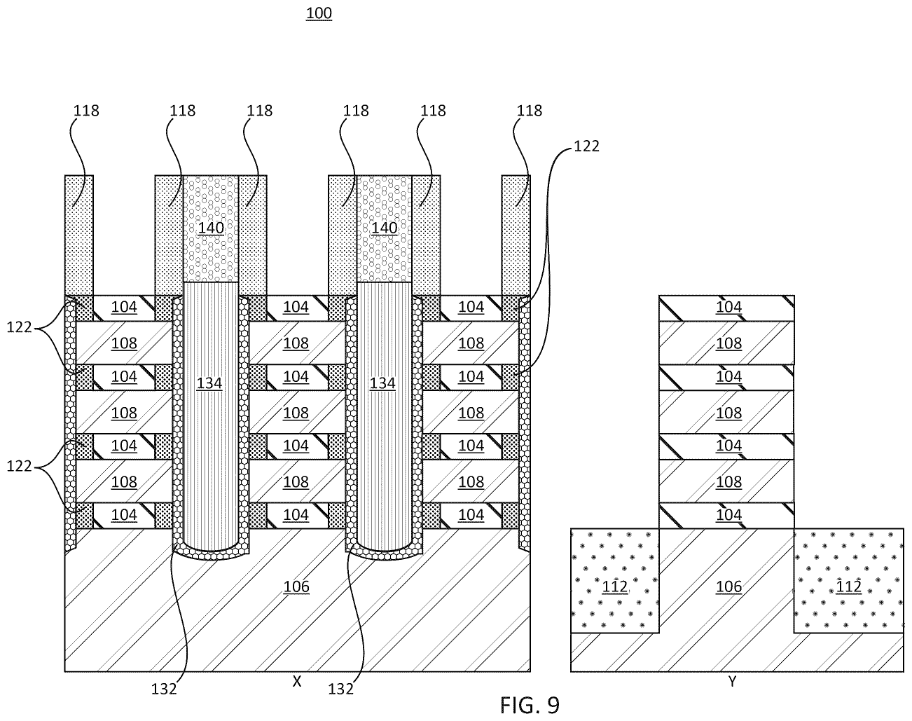

Referring to FIG. 9, dummy gates 114 are selectively removed by a selective etch process. The dummy gates 114 are removed with little or no etching of the spacers 118, the dielectric layer 140, the STI regions 112 and the semiconductor layers 104 and 108.

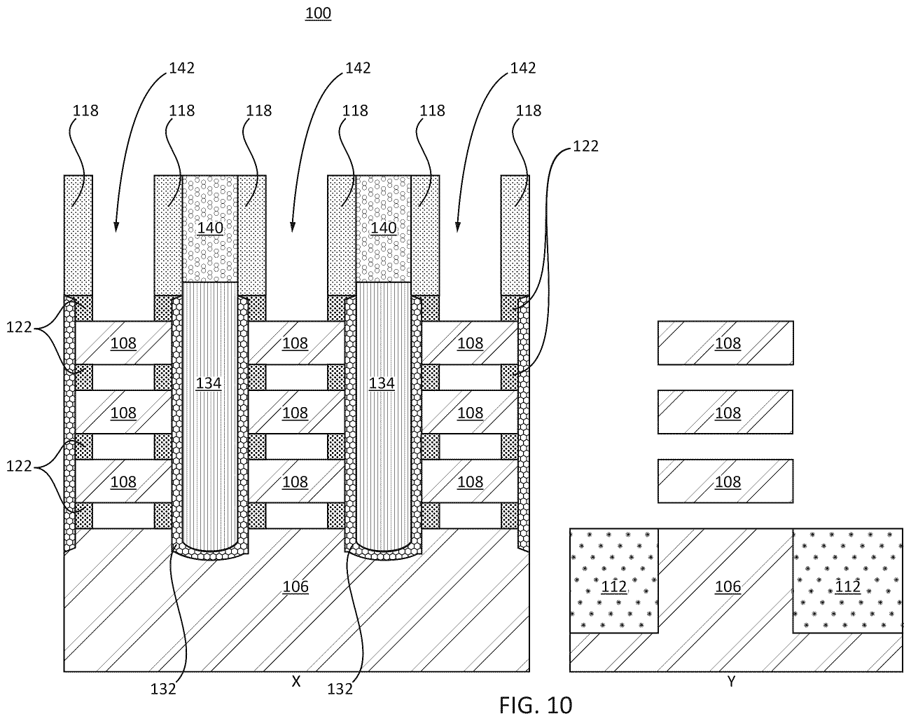

Referring to FIG. 10, with the dummy gates 114 removed, the semiconductor layers 104 are exposed. An etch process is performed to remove the semiconductor layers 104 from gate regions 142 by selectively etching relative to the semiconductor layers 108, the substrate 106, the fillers 122, the spacers 118 and the dielectric layer 140. The compositional difference between the semiconductor layers 104 and the fillers 122 permits the removal of the semiconductor layers 104 without removing the fillers 122. In an embodiment, high SiGe content material of the semiconductor layers 104 is removed relative to the low SiGe content material of the fillers 122.

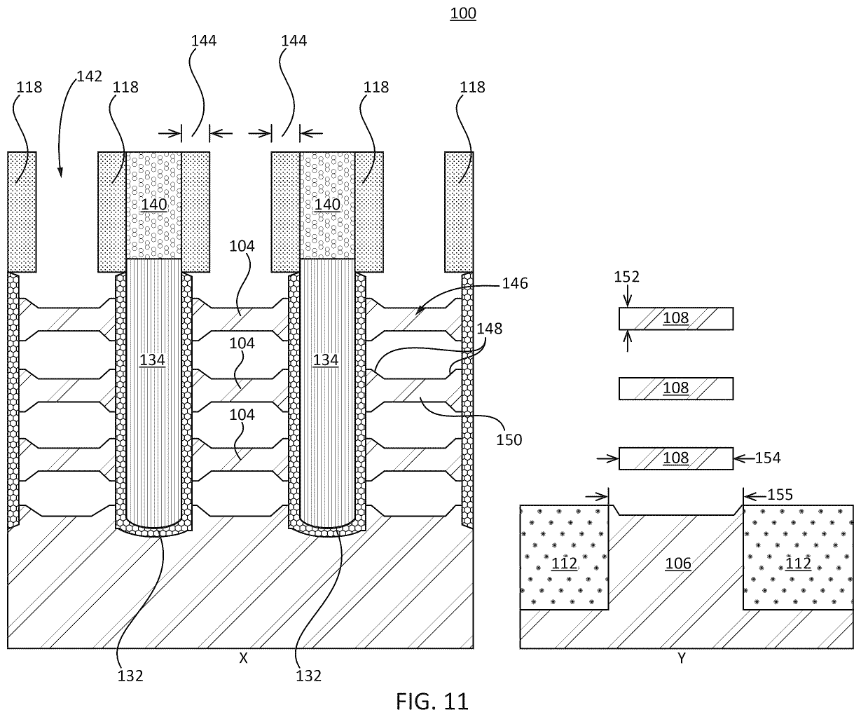

Referring to FIG. 11, dog bone channels 146 are formed by etching the semiconductor layers 104 in the presence of the fillers 122. The presence of the fillers 122 affects the rate at which end portions 148 are etched. In this way, a dog bone profile is achieved where the end portions 148 are wider, and a central portion 150 is thinner. The etch process can include a wet or a dry etch. The chemical concentrations are chosen to remove the fillers 122, and to slowly etch exposed portions of the semiconductor layers 104. This results in the dog bone profile having a diminished thickness 152. In addition, the dog bone profile also has a diminished width 154 for the dog bone channels 146. The diminished width 154 is less than a sheet width 155 of the originally patterned nanosheet. This means that an active area island thickness (e.g., sheet width 155) which represents the originally patterned nanosheet is reduced within an area of the gate (e.g., diminished width 154) and remains its original width (e.g., sheet width 155) outside the gate area (see FIG. 1).

The end portions 148 directly connect with the buffer layer 132 on opposing sides of the dog bone channels 146. The end portions 148 are flared from the central portion 150 to have an increased surface area to contact the buffer layer 132. An interface between the end portions 148 and the buffer layer 132 can occur within a width 144 of the spacers 118. Said differently, at least a portion of the buffer layer 132 and at least a portion of the end portions 148 overlap with the width 144 of the spacers 118.

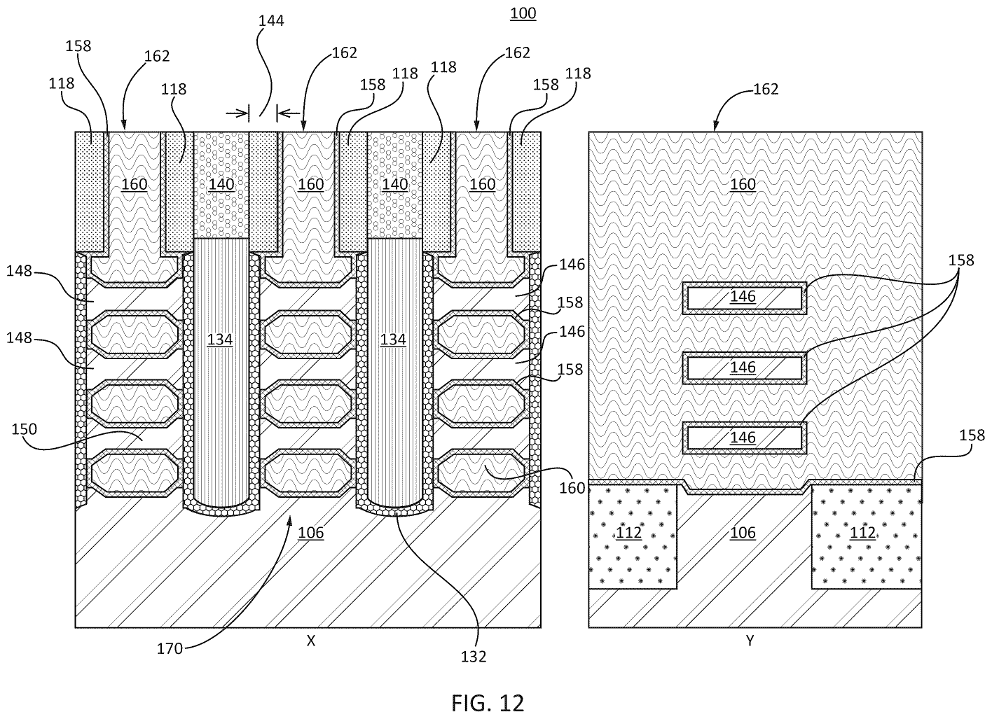

Referring to FIG. 12, a high dielectric constant (high-K) gate dielectric 158 is formed over the dog bone channels 146, the substrate 106, the STI regions 112 and the spacers 118. After the high-K gate dielectric 158 is formed, a gate metal fill is provided to form gate conductors 160. This process is known as a replacement metal gate (RMG) process that forms High-K Metal Gate (HKMG) structures 162 that are employed for selectively activating FETs 170.

The high-K gate dielectric 158 can include a metal oxide(s), such as, hafnium oxide (HfO), hafnium silicon oxide (HfSiO), hafnium silicon oxynitride (HfSiON), lanthanum oxide (LaO), lanthanum aluminum oxide (LaAlO), zirconium oxide (ZrO), zirconium silicon oxide (ZrSiO), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO) and aluminum oxide (AlO). The high-k material may further include dopants such as lanthanum, aluminum, magnesium, or combinations thereof. In a particularly useful embodiment, high-K gate dielectric 158 includes HfO₂. The high-K gate dielectric 158 can be deposited by CVD or other suitable deposition process.

The high-K gate dielectric 158 contacts the buffer layer 132 and the substrate 106 at locations other than locations where the end portions 148 of the dog bone channels 146 contact the buffer layer 132. The high-K gate dielectric 158 (as well as a portion of the gate conductor 160) in contact with the buffer layer 132 also overlaps the width 144 of the spacers 118.

The gate conductors 160 can include any conductive metal including, but not limited to W, Ni, Ti, Mo, Ta, Cu, Pt, Ag, Au, Ru, Ir, Rh, and Re, and alloys that include at least one of these conductive materials. The gate conductor 160 can include one or more layers of conductive materials. In one example, a second conductive material may be formed. When a combination of conductive elements is employed, an optional diffusion barrier material such as TaN or WN may be formed between the conductive materials. The gate conductors 160 can be deposited by CVD, plasma enhanced CVD (PECVD), atomic layer deposition (ALD) or other suitable deposition process.

The dog bone channels 146 improve device performance in a number of ways. For example, the reduced channel profile of the dog bone channels 146 reduces capacitance between channel structures. In addition, resistance between the dog bone channels 146 and the buffer layer 132 (and hence channel to source/drain resistance) is reduced. The dog bone channels 146 also provide better short channel control than devices having inner spacers as part of their structure.

By eliminating the use of inner spacers, compressive strain is easier to maintain within the structure. With increased or higher compressive strain, P-type field effect transistor (PFET) devices can include a higher hole mobility that is more on par with N-type field effect transistor (NFET) devices and electron mobility. This provides better overall device performance and greater short channel effect control.

Next, middle of the line (MOL) contacts (not shown) can be formed to make connections with source/drain regions 130 and gate conductors 160. Processing continues with the formation of back end of the line (BEOL) structures, which can include metal structures within dielectric layers making connections between on-chip and off-chip devices.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
source/drain regions including a main portion and a buffer layer partially encapsulating the main portion; and
dog bone channels extending across a gate conductor and connecting between the buffer layer at end portions of the dog bone channels, the end portions being thicker than a central portion of the dog bone channels.

2. The semiconductor device as recited in claim 1, wherein the gate conductor includes a portion disposed between spacers and the end portions overlap with a width of the spacers.

3. The semiconductor device as recited in claim 2, further comprising a gate dielectric disposed between the dog bone channels and the gate conductor, the gate dielectric including a portion in contact with the buffer layer which overlaps with the width of the spacers.

4. The semiconductor device as recited in claim 2, wherein the gate conductor includes a portion in contact with the buffer layer which overlaps with the width of the spacers.

5. The semiconductor device as recited in claim 1, wherein the buffer layer includes a uniform thickness that encapsulates lateral sides of the main portion.

6. The semiconductor device as recited in claim 1, wherein the dog bone channels include a sheet width thickness that is less than an active area island thickness.

7. The semiconductor device as recited in claim 1, wherein the buffer layer includes monocrystalline or predominately monocrystalline silicon.

8. A semiconductor device, comprising:
a gate structure including:
a gate conductor having a lower portion disposed between source/drain regions and an upper portion;
dog bone channels extending through the gate conductor and connecting between the source/drain regions; and
spacers disposed on sidewalls of the upper portion; and
the source/drain regions including a main portion and a buffer layer encapsulating the main portion, the buffer layer contacting end portions of the dog bone channels, the end portions being thicker than a central portion of the dog bone channels.

9. The semiconductor device as recited in claim 8, wherein the end portions overlap with a width of the spacers.

10. The semiconductor device as recited in claim 9, further comprising a gate dielectric disposed between the dog bone channels and the gate conductor, the gate dielectric including a portion in contact with the buffer layer which overlaps with the width of the spacers.

11. The semiconductor device as recited in claim 9, wherein the gate conductor includes a portion in contact with the buffer layer which overlaps with the width of the spacers.

12. The semiconductor device as recited in claim 8, wherein the buffer layer includes a uniform thickness that encapsulates lateral sides of the main portion.

13. The semiconductor device as recited in claim 8, wherein the dog bone channels include a sheet width thickness that is less than an active area island thickness.

14. The semiconductor device as recited in claim 8, wherein the buffer layer includes monocrystalline or predominately monocrystalline silicon.

15. A semiconductor device, comprising:
a gate structure including:
a gate conductor having a lower portion disposed between source/drain regions and an upper portion;
dog bone channels extending through the gate conductor and connecting between the source/drain regions;
spacers disposed on sidewalls of the upper portion; and
a gate dielectric disposed over the dog bone channels and a surface of the spacers; and
the source/drain regions including a main portion and a buffer layer encapsulating the main portion, the buffer layer having a uniform thickness that encapsulates lateral sides of the main portion, the buffer layer contacting end portions of the dog bone channels, the end portions being thicker than a central portion of the dog bone channels.

16. The semiconductor device as recited in claim 15, wherein the end portions overlap with a width of the spacers.

17. The semiconductor device as recited in claim 15, wherein the gate dielectric includes a portion in contact with the buffer layer which overlaps with a width of the spacers.

18. The semiconductor device as recited in claim 15, wherein the gate conductor includes a portion in contact with the buffer layer which overlaps with a width of the spacers.

19. The semiconductor device as recited in claim 15, wherein the dog bone channels include a sheet width thickness that is less than an active area island thickness.

20. The semiconductor device as recited in claim 15, wherein the buffer layer includes monocrystalline or predominately monocrystalline silicon.
